(19) United States
(12) Patent Application Publication
(10) Pub. No.: US 2011/0099448 A1
(43) Pub. Date: Apr. 28, 2011

(54) SPLIT-ROW DECODING OF LDPC CODES

(76) Inventors: TINOOSH MOHSENIN, Davis, CA (US); Bevan Baas, Davis, CA (US); Pascal Urard, Theys (FR)

(21) Appl. No.: 12/605,078

(22) Filed: Oct. 23, 2009

(51) Int. Cl. H03M 13/05; G06F 11/10

(52) U.S. Cl. 714/752; 714/E11.032

(57) ABSTRACT

A method of decoding a low density parity check (LDPC) encoded block, with the LDPC code being defined by a parity check matrix including rows, includes processing the rows of the parity check matrix. The processing includes updating data in the rows using a split-row decoding algorithm. The updating includes partitioning each row into a plurality of partitions, and determining for each partition a first local minimum of the data of the partition. The method also includes comparing for each partition the first local minimum with a threshold, and updating at least some of the data of all partitions of the row using the local minimums or the threshold depending on the results of the comparing.

### FIELD OF THE INVENTION

The invention relates in general to channel decoding techniques, and more particularly, to the decoding of blocks comprising data previously encoded with a low density parity (LDPC) check code. More specifically, the invention relates to split-row decoding.

### BACKGROUND OF THE INVENTION

Low density parity check (LDPC) codes, which are a class of linear block codes, have received significant attention. This is due to the LDPC codes being near the Shannon limit error correction performance, and the fact that the PDPC codes are inherently based on a parallel decoder architecture.

LDPC codes are a viable option for forward error correction (FEC) systems, and have been adopted by many advanced standards. These standards include a 10 Gigabit Ethernet, digital video broadcasting, and WiMAX.

Implementing high throughput energy efficient LDPC decoders remains a challenge. This is largely due to the high interconnect complexity and high memory bandwidth requirements of existing decoding algorithms stemming from the irregular and global communications inherent in the codes.

An LDPC decoding technique known as Split-Row decoding is based on partitioning the row processing into two or multiple nearly independent partitions, where each block is simultaneously processed using minimal information from an adjacent partition. The key ideas of Split-row decoding are to: 1) simplify row processors, and 2) reduce communications between row and column processors which plays a major role in the interconnect complexity of existing LDPC decoding algorithms. Existing LDPC decoding algorithms include Sum Product (SPA) and MinSum (MS), for example. With this method, parallel operations are increased in the row processing stage, and the complexity of row processors is reduced. Therefore, their circuit area is reduced which results in an overall smaller decoder.

LDPC codes are defined by an M×N binary matrix called the parity check matrix H. The number of columns, represented by N, defines the code length. The number of rows in H, represented by M, defines the number of parity check equations for the code. Column weight W_{c} is the number of ones per column, and row weight Wᵣ is the number of ones per row. LDPC codes can also be described by a bipartite graph or Tanner graph.

An example of a parity check matrix and its corresponding Tanner graph of an LDPC code length N=9 bits is shown in FIG. 1. Each check node Cᵢ corresponding to row i in H is connected to a variable node Vⱼ corresponding to column j in H if a “1” is located at the intersection of row i and column j. LDPC codes can be iteratively decoded in different ways depending on the complexity and error performance requirements. Sum-products (SP) and normalized Min-Sum are near-optimum decoding algorithms that are widely used in LDPC decoders which are known as standard decoders. These algorithms perform row and column operations iteratively using two types of messages: check node messages α, and variable node messages β.

In the Sum-Product algorithm (SP) during the row processing or check node update stage, each check node Ci computes the α message for each variable node V_{j′}, j′≠j which is connected to Ci. In this stage, α is computed as follows:

$$\begin{matrix}{α}_{ij} = {\prod }_{{j}^{′} ∈ V ( i ) / j} sign ( {β}_{{ij}^{′}} ) \times φ ( {\sum }_{{j}^{′} ∈ V ( i ) / j} φ ( \vert {β}_{{ij}^{′}} \vert ) ) \\ where , & ( 1 ) \\ φ ( x ) = - log ( tanh \frac{\vert x \vert}{2} ) & ( 2 )\end{matrix}$$

With V(i)={j:Hᵢⱼ=1} defining the set of variable nodes which participate in the check equation i, C(j)={i:Hᵢⱼ=1} denotes the set of check nodes taking part in the variable node j update, V(i)\j denotes all variable nodes in V(i) except node j, and C(j)\i denotes all the check nodes in C(j) except node i.

The first product term in equation (1) is called the parity (sign) update, and the second product term is the reliability (magnitude) update. In column processing, which is also called the variable node update stage, each variable node Vⱼ computes the β message for check node Cᵢ by adding the received information from the channel corresponding to column j (called λ), and α messages from all other check nodes C_{i′}, where i′≠i and which is connected to Vⱼ, as indicated in equation (3):

$${β}_{ij} = {λ}_{j} + {\sum }_{{i}^{′} ∈ C ( j ) / i} {α}_{{i}^{′} j} \qquad ( 3 )$$

The check node or row processing stage of SP decoding can be simplified by approximating the magnitude computation in equation (1) with a minimum function. The algorithm using this approximation is called Min-Sum (MS).

$${α}_{ij} = {\prod }_{{j}^{′} ∈ V ( i ) / j} sign ( {β}_{{ij}^{′}} ) x {min}_{{j}^{′} ∈ V ( i ) / j} ( \vert {β}_{{ij}^{′}} \vert ) \qquad ( 4 )$$

In MS decoding, the column operation is the same as in SP decoding. The error performance loss of MS decoding can be improved by scaling the check (α) values in equation 4 with a scale factor S≦1 which normalizes the approximations.

Another known decoding method is called Spit-row decoding. The article “Split-Row: A Reduced Complexity, High Throughput LDPC Decoder Architecture”, published in the IEEE International Conference on Computer Design in 2006, and written by T. Mohsenin and B. M. Baas, describes a Split-Row LDPC decoding method in which the row processing stage is divided into two almost independent halves.

To illustrate an example of Split-Row decoding, FIG. 2a shows a block diagram and a parity check matrix example of a 12-bit LDPC code highlighting the first row processing stage using MinSum decoding. The row processor output is shown by α and the column processor output is shown by β, which is used by the row processor in the next iteration. The check node C₁ corresponding to a first row of parity check matrix is also shown at the bottom, which connects to four variables nodes.

In the Split-Row method which is shown in FIG. 2b, row processing is partitioned into two blocks, for example, where each block is simultaneously processed almost independently. With this partitioning, the number of inputs sent to check node C₁ in each partition is reduced to half. This results in less communications between row and column processors. In addition, each row processor's circuit area is reduced because it processes only half the number of inputs.

The above mentioned MinSum approximation may be also used in the Split-row decoding method leading to a so called MinSum Split-Row decoding method. Equations (5) and (6) below, show the row processing equations of the MinSum normalized and MinSum Split-Row decoding methods.

$$\begin{matrix}{α}_{ij} = {S}_{MS} x {\prod }_{{j}^{′} ∈ V ( i ) / j} sign ( {β}_{{ij}^{′}} ) x {min}_{{j}^{′} ∈ V ( i ) / j} ( \vert β {ij}^{′} \vert ) & ( 5 ) \\ {α}_{ij} Split = {S}_{Split} x {\prod }_{{j}^{′} ∈ V ( i ) / j} sign ( \vert {β}_{{ij}^{′}} \vert ) x {min}_{{j}^{′} ∈ {v}_{split} ( i ) / j} ( \vert {β}_{{ij}^{′}} \vert ) & ( 6 )\end{matrix}$$

In the above equations, β is the input to row processing and α is the output of row processing. In MinSum Split-Row the sign bit is computed using the sign bit of all messages across the whole row of parity check matrix. This is because the sign is passed to the next partition. However, the magnitude of the α message in each partition is computed by finding the minimum among the messages within each partition. S_{MS} and S_{Split} are correction factors which normalize α values in MinSum and MinSum Split-Row to improve the error performance.

The above described partitioning architectures have three major benefits which are doubling parallel operations in the row processing stage, decreasing the number of memory accesses per row processor, and making each row processor simpler. These three factors combine to make row processors, and therefore the entire LDPC decoder, smaller, faster and more energy efficient. In addition, the Split-Row method makes parallel operations in the column processing stage easier to exploit. To reduce performance loss due to errors from this simplification, the sign computed from each row processor is passed to its corresponding half processor with a single wire in each direction. These are the only wires between the two halves.

An improved decoding method is called, Multiple Split-Row. The article, “High-Throughput LDPC Decoders Using A Multiple Split-Row Method,” published in the proceedings of the IEEE International Conference on Acoustics, Speech, and Signal Processing in 2007, and written by T. Mohsenin and B. M. Baas, describes a generalized Split-Row decoding method in which the row processing stage can be divided into more than two almost-independent partitions. Part of the design process involves determining the optimum number of partitions since a large number of partitions results in more efficient hardware, but also results in a larger bit-error-rate (BER).

Using the MinSum Split-Row and Multiple Split-Row methods, the chip implementation results show significant improvements in circuit area, decoder throughput, and energy dissipation over the MinSum decoder, particularly for long codes with large row weights.

The major problem in MinSum Split-Row is that it suffers, in certain applications, from 0.4 to 0.7 dB error performance loss. This loss depends on the number of row partitions compared to MinSum and SPA decoders.

In MinSum decoding, the check node processing in question has two parts: sign and magnitude. In MinSum Split-Row, the sign computation is realized the same way as in MinSum, but for magnitude update the use of a local minimum in each partition helps reduce the communication. Therefore, the main reason for error performance degradation is that in MinSum Split-Row each partition has no information about the minimum value of the other partitions. Therefore, when the minimum value in one partition is much larger than the global minimum, the a values in that partition which are calculated by that minimum are all over estimated when compared to those in the partition. This leads to a possible incorrect estimation of the bits that reside in that partition.

An example of such an incorrect estimation is illustrated in FIGS. 3a and 3b. FIG. 3a shows another parity check matrix example while FIG. 3b shows the values in the first row of this parity check matrix after having been initialized with the received channel data. According to the MinSum Split-Row decoding method, the local minimum in each partition is calculated independently and is used to update the α values. However, as shown in the figure, the local minimum in the left side partition, Min sp0, is 3 which is ten times larger than the local minimum in the right side partition, Min sp1, 0.3 which is also the global minimum of the entire row. This results in a large over estimation of α values which can possibly cause an incorrect decision for these two bits in the left side partition, as compared to MinSum in which the global minimum is used across the row.

### SUMMARY OF THE INVENTION

In view of the foregoing background, an object of the present invention is to provide a decoding method based on a Split-Row Threshold decoding. The Split-Row Threshold decoding is to compensate for the difference between the local minimums of the partitions while enabling a very high throughput, and while providing a high energy efficient decoder with a small circuit area that is well suited for long codes with large row weights. The method is also easy to implement using automatic place and route CAD (Computer Aided Design) tools, and has good error performance.

Thus, according to one aspect, a method of decoding an LDPC encoded block is provided, wherein the LDPC code may be defined by a parity check matrix that includes rows. The method may comprise receiving the encoded block, and processing the rows including updating data of the rows using a Split-Row decoding algorithm. This updating may include partitioning each row into several partitions and determining, for each partition, a first local minimum of the data of the partition.

The row processing may further comprise for each row, comparing for each partition a first local minimum with a threshold, and updating at least some of the data of all partitions of the row using either the local minimum of the threshold value depending on the results of the comparisons.

According to an embodiment:

a) if the first local minimum of a partition is smaller or equal to the threshold, then the first local minimum may be used to update some data of the partition;

b) if the first local minimum of a partition is bigger than the threshold, while the local minimum of at least another partition is smaller than the threshold, then the data of the partition may be updated with the threshold value; and

c) if the first local minimum of each partition is bigger than the threshold, then the first local minimum of a partition may be used to update some data of this partition.

Each partition may send to all other partitions a signal representative of the result of the comparison performed within the partition.

A second local minimum may be determined in each block. The second local minimum may be used to update the value of the first local minimum of the partition in cases a) and c).

The encoded block may be received from a channel, and the threshold may be dependent on the size and row weight of the code but is independent of the signal-to-noise ratio in a channel with additive white Gaussian noise (known as AWGN). In AWGN channels with binary phase shift keying (known as BPSK) modulation, the threshold value may be chosen between 0.1 and 0.5 for some LDPC codes. For example, with an (6,32)(2048,1723) LDPC code and split-2, the optimal values fall between 0.1 and 0.2.

According to another aspect, an LDPC decoding device may comprise reception means or circuitry to receive an LDPC encoded block. The LDPC code may be defined by a parity check matrix including rows, where each row may be partitioned into several partitions. The LDPC decoding device may further comprise row processing means or circuitry coupled to the reception means. The row processing circuitry means may update data of the rows using a Split-Row decoding algorithm. The processing circuitry may comprise determining means or circuitry to determine, for each partition, a first local minimum among the data of the partition. The LDPC decoding device may also comprise comparison means or circuitry to compare the first local minimum of each partition of each row with the threshold. Updating means or circuitry may be used to update, for each row, at least some of the data of all the partitions of the row using either the local minimums of the threshold value depending on the results of the comparisons.

The updating circuitry may be configured to use:

a) the first local minimum of a partition to update some data of the partition, if the first local minimum of the local partition is smaller or equal to the threshold;

b) the threshold value to update the data of a partition, if the first local minimum of the partition is bigger than the threshold, while the first local minimum of at least another partition is smaller than the threshold; and

c) the first local minimum of a partition to update some data of the partition, if the first local minimum of each partition is bigger than the threshold.

The comparing circuitry may be configured to compare for each partition the first local minimum of the partition with the threshold, and to deliver to the updating means the signal representative of the result of the comparison performed within the partition.

The determining circuitry may be able to determine a second local minimum in each partition. The second local minimum may be used to update the value of the first local minimum after the partition in cases a) and c).

In another aspect, a receiver comprises an LDPC decoding device as defined above.

In yet another aspect, a communication system comprises a transceiver and a receiver as defined above.

A more detailed but non-restrictive example of a split-row threshold decoding method has been presented on Oct. 26, 2008 in an IEEE Asilomar 2008 Conference, in California by Tinoosh Mohsenin, Pascal Urard and Bevan Baas. The example is titled “A Thresholding Algorithm for improved Split-Row Decoding of LDPC Codes”.

### BRIEF DESCRIPTION OF THE DRAWINGS

Other advantages and characteristics of the decoding will appear in the detailed description and in the appended drawings, and are not to be viewed as being limiting, in which:

FIG. 1 illustrates an example of a parity check matrix and a Tanner graph representation of an LDPC code with code length N=9 bits in accordance with the prior art;

FIGS. 2a and 2b illustrate an example of a block diagram with a parity check matrix and its associated Tanner graph highlighting the first row processing and a check node C₁ for (2a) MinSum and (2b) MinSum Split-Row decoding methods in accordance with the prior art;

FIGS. 3a and 3b illustrate the parity check matrix of a 12-bit LDPC code highlighting the first row processing using (3a) original Split-Row decoding and (3b) after being initialized with the channel information, where Min Sp0>>Min Sp1, in accordance with the prior art;

FIGS. 4, 5a and 5b illustrate embodiments of a decoding method in accordance with the present invention;

FIGS. 6 an 7 illustrate a decoder in accordance with the present invention;

FIGS. 8 and 9 are plots illustrating results and advantages in accordance with the present invention; and

FIG. 10 illustrates a wireless communication system including a receiver comprising a decoding device in accordance with the present invention.

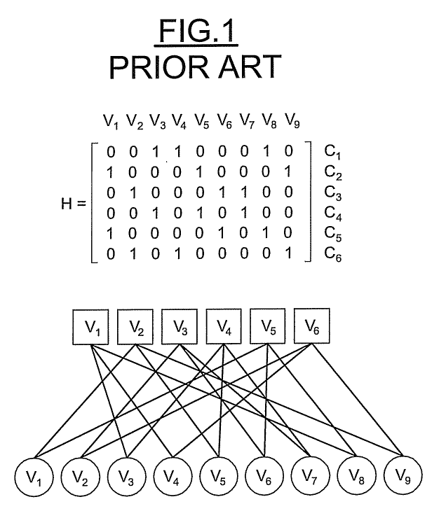

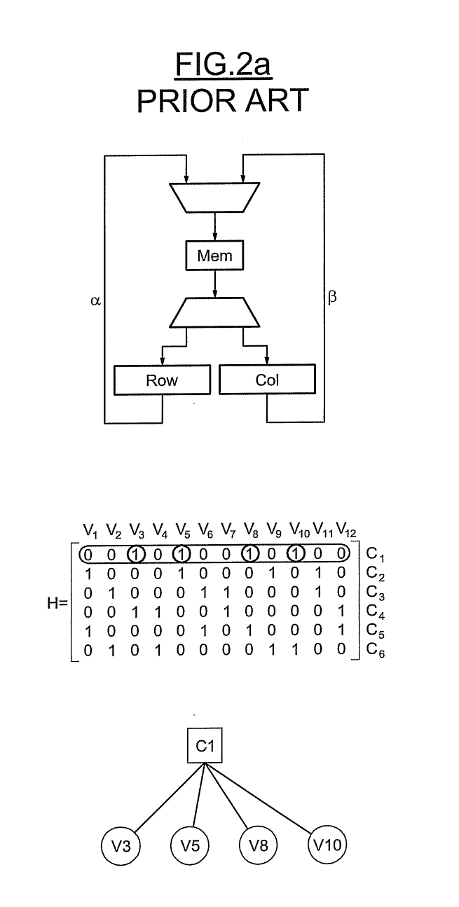

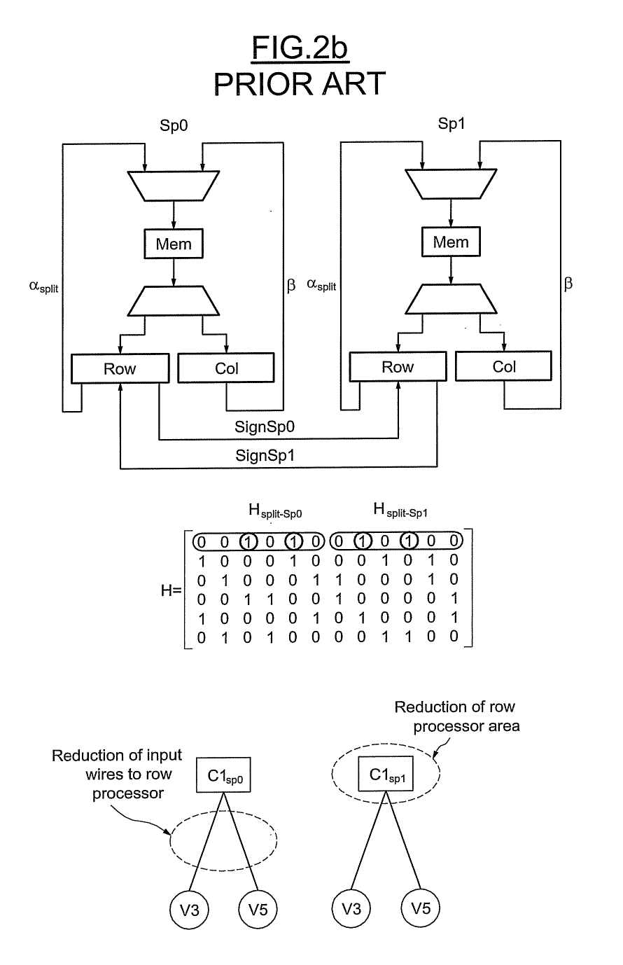

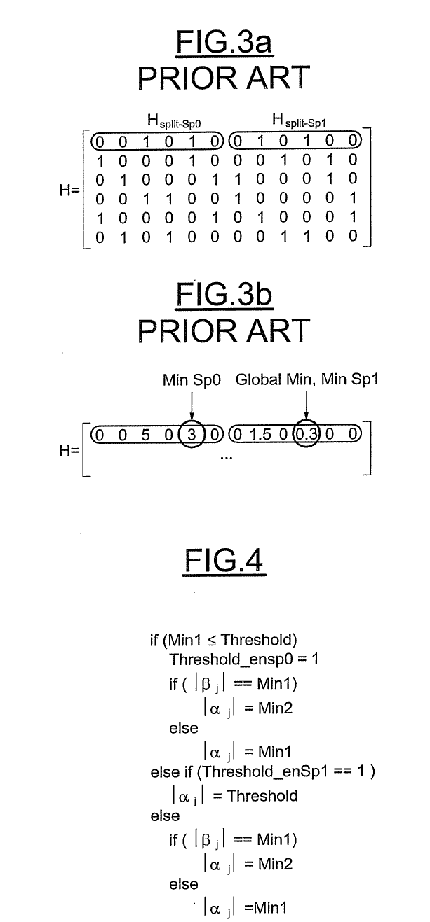

### DETAILED DESCRIPTION OF THE PREFERRED EMBODIMENTS

According to one aspect for the row processing, a threshold decoding method is based on Split-Row to compensate for the difference between the local minimums of the partitions. This improves the error performance with negligible additional hardware. The basic idea is that each partition sends a signal to the next partition if its own local minimum is smaller than a threshold T. Thus, the other partitions are notified if a local minimum smaller than the threshold T exists.

A non-limiting embodiment of such a Split-Row Threshold decoding method is illustrated in FIG. 4 with two partitions Sp0 and Sp1.

Similar to the MinSum decoding method, after an initializing step using the received channel values, a first local minimum Min1 and a second local minimum Min2 in each partition are locally determined. For the Row processing, the proposed method checks if the first local minimum is less than the threshold T. If it is the case, then both first and second local minimums Min1 and Min2 are used to update α values (case a)). In other words, in case a), if the first local minimum Min1 of a partition Sp0 is smaller or equal to the threshold, then the first local minimum Min1 is used to update some data of the partition Sp0. More particularly, the data of the partition Sp0 is updated except the first local minimum Min1 itself.

The first local minimum Min1 is updated with the second local minimum Min2 of the partition Sp0.

Additionally, a binary threshold signal Threshold_enSp0 is sent to another partition to indicate if the first local minimum Min1 in this partition Sp0 is smaller than the threshold T. If the first local minimum Min1 is smaller than the threshold T, then the binary signal Threshold_enSp0 has a non-zero value. Otherwise, the value of the binary signal Threshold_enSp0 is equal to zero.

If the first local minimum Min1 of a partition Sp0 is larger than the threshold T while a threshold signal Threshold_enSp1 from a neighboring partition Sp1 has a non-zero value, i.e., is equal to 1, for example, then the threshold value T is used to update α values in that partition Sp0(case b)). In other words, in case b), if the first local minimum Min1 Sp0of a partition Sp0 is bigger than the threshold T while the local minimum Min1 Sp1 of at least another partition Sp1 is smaller than the threshold T, then the data of the partition Sp0 is updated with the threshold value T.

The last condition is when a first local minimum Min1 is larger than the threshold value T, and all the threshold signals from the other partitions are equal. This indicates that the first local minimums in the other partitions are also larger than the threshold T. In this case, the first local minimum Mint and second local minimum Min2 are used to calculate a values (case c)). In other words, if the first local minimum Min1 of each partition Sp0 is bigger than the threshold T, then the first local minimum Min1 of a partition Sp0 is used to update some data of this partition Sp0. More particularly, the data of the partition Sp0 is updated except for the first local minimum Min1 itself.

The first local minimum Min1 is updated with the second local minimum Min2 of the partition. Column processing in the MinSum Split-Row Threshold is identical to the column processing of MinSum Split-Row decoding, for example.

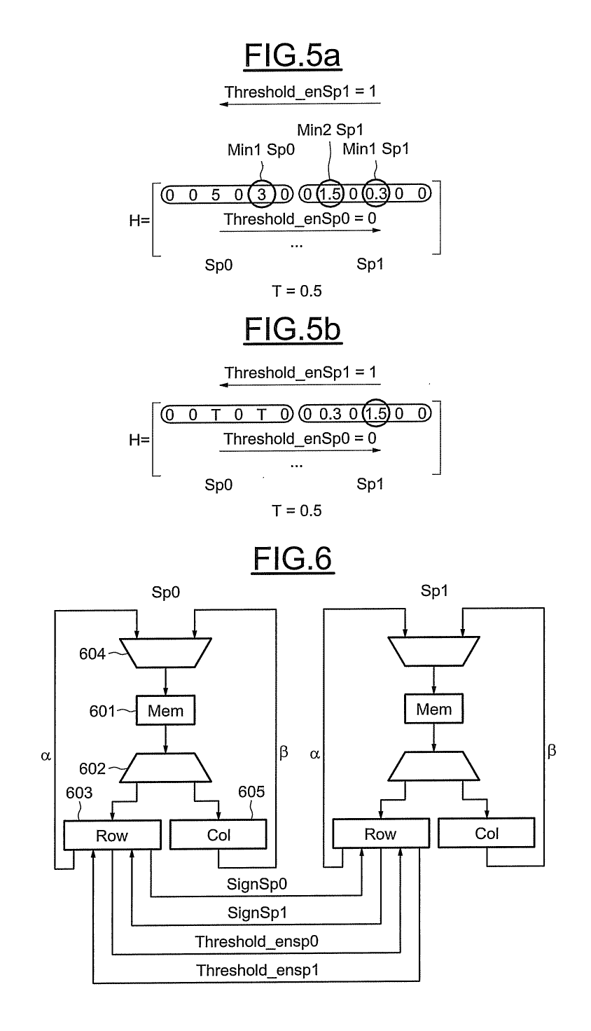

An example of such a Split-Row Threshold decoding method is illustrated in FIGS. 5a and 5b. In FIG. 5a, the threshold value has been set at T=0.5, and the row is split into two partitions Sp0 and Sp1. The first local minimum Min1 Sp1 of the second partition Sp1 is lower than the threshold T which is equal to 0.3. Therefore, the values of the second partitions Sp1 will be updated in FIG. 5b with the first local minimum value Min1 Sp1, except for the first local minimum Min1 Sp1 which will be updated with the second local minimum Min2 Sp1 of the second partition Sp1.

The first local minimum Min1 Sp0 of the first partition Sp0 is equal to 3.

Therefore, it is above the threshold value T while the first local minimum Min1 Sp1 of the second partition Sp1 is lower than the threshold T which is equal to 0.3. Thus, the first partition Sp0 receives a threshold signal Threshold_enSp1 from the second partition Sp1 equal to 1. Therefore, the values of the first partition Sp0 are updated in FIG. 5b with the threshold value T.

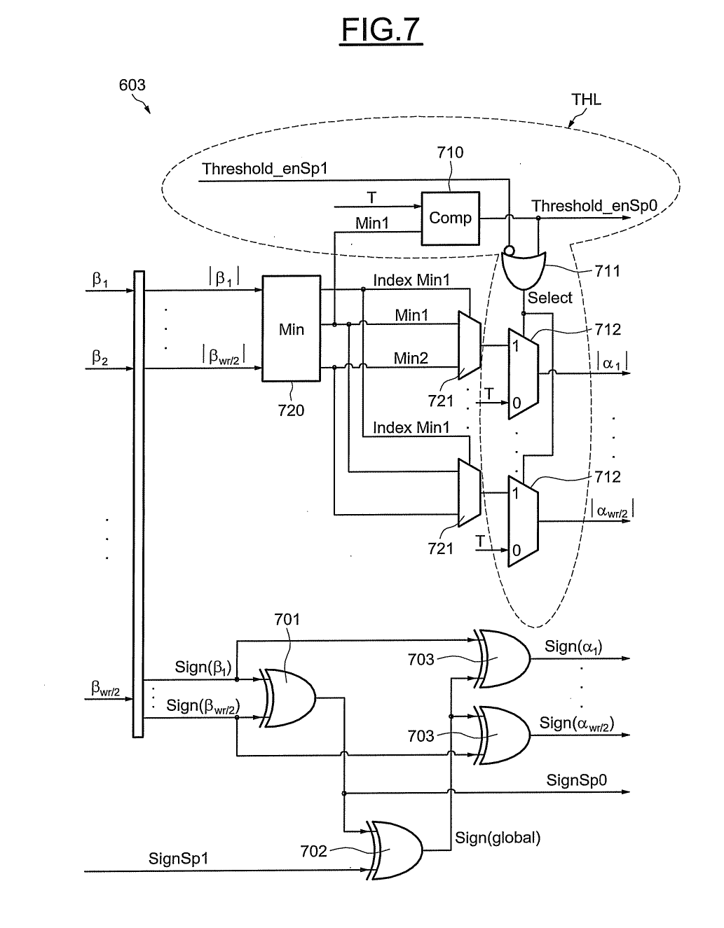

FIG. 6 illustrates an example of a block diagram of an LDPC decoding device configured to implement a Split-Row Threshold decoding where the threshold signals are passed between two partitions using two wires in addition to the two sign wires. Briefly, the LDPC decoder comprises for each partition, row processing means or circuitry 603 and column processing means or circuitry 605 mutually interconnected though multiplexers 602 and 604 and memory means or circuitry 601.

The row processor 603 delivers a sign signal SignSp0, which is a binary signal corresponding to the sign of the first partition Sp0 and the threshold signal Threshold_enSp0. At the same time, it receives the sign signal SignSp1 from the second partition Sp1 and the threshold signal Threshold_enSp1.

The row processor 603 then delivers the updated α values. At the same time, an identical process is realized on the other partitions, which is on the second Sp1 partition.

FIG. 7 represents in greater detail an example of a row processor 603 using a MinSum Split-Row Threshold decoding method. The implementation of the row processor in the MinSum Split-Row Threshold is similar than that of a MinSum decoder. An exception is that it may only need half of the total number of inputs β and a small additional hardware, in a case where a row is partitioned in two. The column processor implementation remains the same as in the MinSum and MinSum Split-Row.

The magnitude update of α is shown on the top of the figure and the calculated signs are shown at the bottom part of the figure. In this example, only two partitions have been considered for a row, but the row can be split into as many partitions as it possibly can.

As illustrated in this figure and similar to a MinSum Split-row, the sign bit SignSp1 calculated from the second partition Sp1 is passed to the first partition Sp0 to correctly calculate the global sign bit Sign(global) according to row processing equation (6). The first partition sign SignSp0 is determined using an XOR gate 701 that receives and processes the sign bits Sign(βₙ) of the inputs, i.e., data in the partition. In this example, the data corresponds to half of the data of the row. To calculate the global sign bit Sign(global), another XOR gate 702 collects the signs of the first and second partition SignSp0 and SignSp1 and delivers the resulting sign of the row Sign(global). This resulting sign Sign(global) is then delivered to XOR gates 703, wherein each one also receives a sign Sign(βₙ) of an input β. The XOR gates 703 deliver the resulting sign Sign(αₙ) of the magnitude value associated αₙ therewith.

The threshold logic implementation THL is shown within the dashed line. It comprises a comparator 710, an OR gate 711 and wr/2 first muxes 712. Assuming the row weight of the parity check matrix is wr, there are wr/2 inputs β to each row processor. Similar to the MinSum decoding method, the first local minimum Mint and the second local minimum Min2 are found using detecting means or circuitry 720. A logical index signalIndexMin1 indicates to the second muxes 721 whether the first local minimum or the second local minimum is chosen for updating the value αᵢ.

The first local minimum Min1 is then compared using comparator 710 with the threshold T to generate the threshold signal Threshold_enSp0 of the first partition Sp0. This does not add extra delay because the second local minimum Min2 is generated one comparator delay after the first local minimum Min1.

The threshold signal Threshold_enSp0of the first partition Sp0 and the threshold signal Threshold_enSp1 of the second partition Sp1 are combined together to generate the selecting signal Select corresponding to the combination by the OR gate 711 of the threshold signal of the first partition Threshold_enSp0 with the opposite signal of the threshold signal second partition T̅h̅r̅e̅s̅h̅o̅l̅h̅d̅_̅e̅n̅S̅p̅1̅. The selecting signal Select is then delivered to the first muxes 712 wherein each one receives a signal issued from one of the second muxes 721. This permits the α values to be finally produced using the selecting signal Select and the signal values Min1 or Min2.

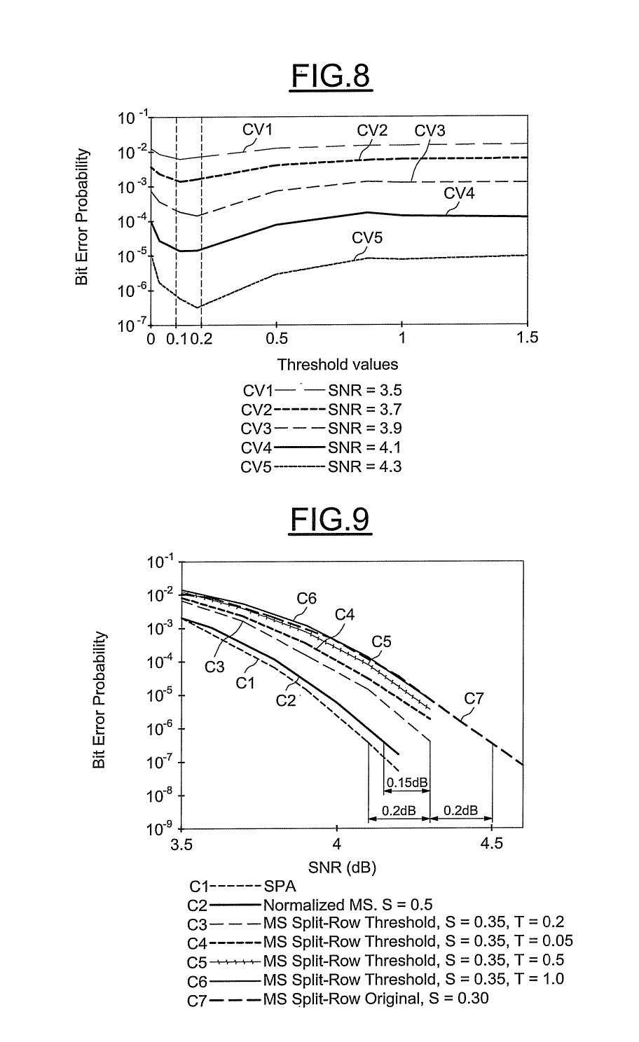

To show the effect of choosing the optimal threshold value, FIG. 8 plots the bit error performance of an LDPC code with a code length of 2048 bits, an information length of 1723 bits, a column weight of 6 and a row weight of 32 (shown as (6,32)(2048,1723) LDPC code) versus threshold values for different SNRs. There are two limits for the threshold values. If the threshold is zero, then the local minimums are always larger than the threshold. This means that the local minimums are used to update α. Thus, the method converges to the original MinSum Split-Row. If the threshold is very large, the local minimums are always smaller than the threshold. This again results in using local minimums to calculate α. Therefore, the method converges to the original MinSum Split-Row. As shown in the figure, the optimal value of the threshold for this code, within the SNR ranges of 3.5 to 4.3 dbs, is in the interval of 0.1 to 0.2. Thus, one of the benefits of the MinSum Split-Row Threshold method is that the threshold value changes are very small with different SNR values for channels with AWGN noise.

FIG. 9 also shows the bit error performance results for a (6,32)(2048,1723) LDPC code for SPA, MinSum normalized, MinSum Split-Row original and MinSum Split-Row Threshold with different threshold values using AWGN noise and BPSK modulation. The simulation results show that the optimal correction factor S for MinSum is 0.5, for MinSum Split-Row original is 0.30, and for MinSum Split-Row Threshold is 0.35. The threshold was chosen to be fixed over different SNRs and different decoding iterations. As shown in the figure, a decoding gain of MinSum Split-Row Threshold, with T=0.2, over the original is 0.2 dB, and it is only 0.15 dB away from MinSum normalized.

The threshold Split-Row LDPC decoding method facilitates hardware implementation capable of high throughput, high hardware efficiency and high energy efficiency. The simulation results show that the Split-Row Threshold LDPC decoding method outperforms the Split-Row algorithms for 0.2 dB while maintaining the same level of complexity. The simulation results show that for a given LDPC code keeping a threshold constant at any SNR does not cause any error performance degradation.

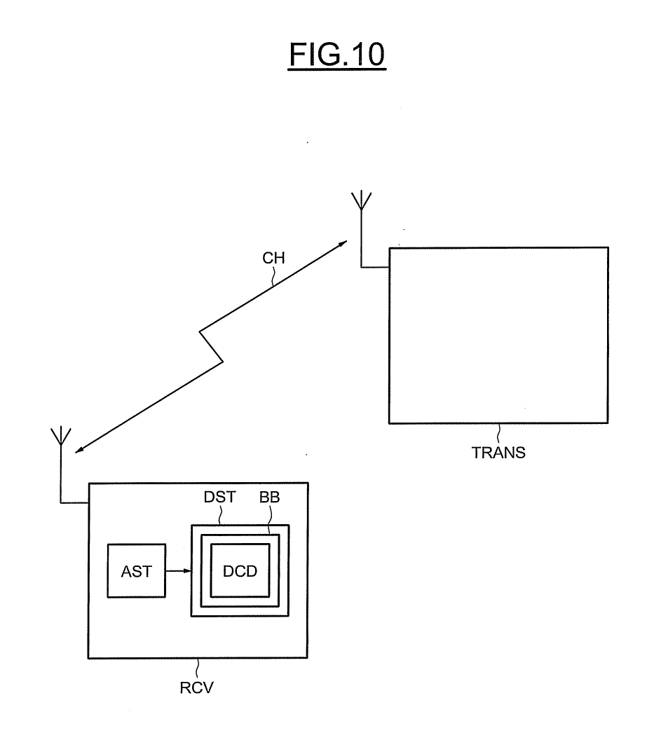

As shown in FIG. 10, the above described decoder DCD may be incorporated in the baseband processor BB of the digital stage of a wireless receiver RCV, for example. The wireless receiver RCV may be a mobile phone, for example. The receiver includes an analog stage receiving the signal using an antenna, and delivers the signal to the digital stage. The receiver belongs to a wireless communications system including a transmitter TRANS transmitting a signal to a receiver RCV through a channel CH.

That which is claimed is:

1. A method of decoding a low density parity check (LDPC) encoded block, with the LDPC code being defined by a parity check matrix including rows, the method comprising:
receiving the LDPC encoded block; and
processing the rows of the parity check matrix, the processing comprising
updating data in the rows using a split-row decoding algorithm, the updating including partitioning each row into a plurality of partitions, and determining for each partition a first local minimum of the data of the partition,
comparing for each partition the first local minimum with a threshold, and
updating at least some of the data of all partitions of the row using the local minimums or the threshold depending on the results of the comparing.

2. The method according to claim 1, wherein:
a) if the first local minimum of a partition is smaller or equal to the threshold, then the first local minimum is used to update some data of the partition;
b) if the first local minimum of a partition is larger than the threshold while the local minimum of at least another partition is smaller than the threshold, then the data of the partition is updated with the threshold; and
c) if the first local minimum of each partition is larger than the threshold, then the first local minimum of a partition is used to update some data of this partition.

3. The method according to claim 2, wherein each partition provides to all other partitions a signal representative of a result of the comparing performed within the partition.

4. The method according to claim 2, wherein a second local minimum is determined in each partition, with the second local minimum being used to update a value of the first local minimum in a) and c).

5. The method according to claim 1, wherein the LDPC encoded block is received from a channel, and the threshold is independent of a signal-to-noise ratio of the channel.

6. The method according to claim 1, wherein the threshold is within a range of 0.1 and 0.5.

7. A low density parity check (LDPC) decoding device comprising:
reception circuitry configured to receive an LDPC encoded block, with the LDPC code being defined by a parity check matrix including rows, with each row being partitioned into several partitions; and
row processing circuitry coupled to said reception circuitry and configured to update data of the rows using a split-row decoding algorithm, said row processing circuitry comprising
determining circuitry configured to determine for each partition a first local minimum of the data of the partition,
comparing circuitry configured to compare the first local minimum of each partition of each row with a threshold, and
updating circuitry configured to update for each row at least some of the data of all the partitions of the row using the local minimums or the threshold depending on the results of said comparisons.

8. The LDPC decoding device according to claim 7, wherein said updating circuitry is configured to use:
a) the first local minimum of a partition to update some data of the partition if the first local minimum of the partition is smaller or equal to the threshold;
b) the threshold to update the data of a partition if the first local minimum of the partition is larger than the threshold while the first local minimum of at least another partition is smaller than the threshold; and
c) the first local minimum of a partition to update some data of the partition if the first local minimum of each partition is larger than the threshold.

9. The LDPC decoding device according to claim 8, wherein said comparing circuitry is configured to compare for each partition the first local minimum of a partition with the threshold, and to deliver the updating as a signal representative of a result of the comparing performed within the partition.

10. The LDPC decoding device according to claim 8, wherein a second local minimum is determined in each partition, with the second local minimum being used to update a value of the first local minimum in a) and c).

11. The LDPC decoding device according to claim 7, wherein the LDPC encoded block is received from a channel, and the threshold is independent of a signal-to-noise ratio of the channel.

12. The LDPC decoding device according to claim 7, wherein the threshold is within a range of 0.1 and 0.5.

13. A communications device comprising:
an analog stage configured to receive an LDPC encoded block, with the LDPC code being defined by a parity check matrix including rows, with each row being partitioned into several partitions; and
a digital stage coupled to said analog stage and comprising row processing circuitry and configured to update data of the rows using a split-row decoding algorithm, said row processing circuitry comprising
determining circuitry configured to determine for each partition a first local minimum of the data of the partition,
comparing circuitry configured to compare the first local minimum of each partition of each row with a threshold, and
updating circuitry configured to update for each row at least some of the data of all the partitions of the row using the local minimums or the threshold depending on the results of said comparisons.

14. The communications device according to claim 13, wherein said updating circuitry is configured to use:
a) the first local minimum of a partition to update some data of the partition if the first local minimum of the partition is smaller or equal to the threshold;
b) the threshold to update the data of a partition if the first local minimum of the partition is larger than the threshold while the first local minimum of at least another partition is smaller than the threshold; and
c) the first local minimum of a partition to update some data of the partition if the first local minimum of each partition is larger than the threshold.

15. The communications device according to claim 14, wherein said comparing circuitry is configured to compare for each partition the first local minimum of a partition with the threshold, and to deliver the updating as a signal representative of a result of the comparing performed within the partition.

16. The communications device according to claim 14, wherein a second local minimum is determined in each partition, with the second local minimum being used to update a value of the first local minimum in a) and c).

17. The communications device according to claim 13, further comprising an antenna coupled to said analog stage, and wherein the LDPC encoded block is received over a channel via said antenna, and the threshold is independent of a signal-to-noise ratio of the channel.

18. The communications device according to claim 13, wherein the threshold is within a range of 0.1 and 0.5.

19. The communications device according to claim 13, wherein the analog and digital stages are configured as a cell phone.
